(19) United States
(12) Patent Application Publication
(10) Pub. No.: US 2025/0362471 A1
(43) Pub. Date: Nov. 27, 2025

(54) HOLDING APPARATUS, APPARATUS FOR EXPOSING SUBSTRATE, MEASUREMENT APPARATUS, METHOD FOR MANUFACTURING OPTICAL DEVICE, AND METHOD FOR MANUFACTURING PRODUCT

(71) Applicant: CANON KABUSHIKI KAISHA, Tokyo (JP)

(72) Inventors: SO TAKEUCHI, Tochigi (JP); NAOKI FUNABASHI, Tochigi (JP); WATARU YAMAGUCHI, Tochigi (JP); SHINICHI SHIMA, Tochigi (JP)

(21) Appl. No.: 19/202,446

(22) Filed: May 8, 2025

(30) Foreign Application Priority Data
May 21, 2024 (JP) 2024-082899

(51) Int. Cl. G02B 7/02; G03F 9/00

(52) U.S. Cl. CPC G02B 7/021; G03F 9/7019; G03F 9/7088; G03F 9/7096

(57) ABSTRACT

In a holding apparatus, a first holding unit has a first surface at a position facing a lens barrel, the first surface being inclined with respect to an optical axis of a first optical element, a second holding unit has a second surface at a position facing the lens barrel, the second surface being inclined with respect to an optical axis of a second optical element, and the lens barrel includes a first through-hole that is provided at a position corresponding to the first surface and extends in a first direction orthogonal to the optical axis of the first optical element, and a second through-hole that is provided at a position corresponding to the second surface and extends in a second direction orthogonal to the optical axis of the second optical element.

### BACKGROUND

### Field

The present disclosure relates to a holding apparatus, an apparatus for exposing a substrate, a measurement apparatus, a method for manufacturing an optical device, and a method for manufacturing a product.

### Description of the Related Art

Processes for manufacture of a semiconductor device and a liquid crystal display device may use an objective lens. The objective lens is included in, for example, a projection optical system that projects light from a light source to an object, and a measurement optical system that measures the position of an object. The position of a lens included in the objective lens is being accurately adjusted in a direction orthogonal to an optical axis of the lens in addition to a direction parallel to the optical axis.

Japanese Patent Application Laid-Open No. 2004-219608 discusses a method for adjusting the position of a lens in a direction orthogonal to an optical axis of the lens by moving the lens by applying a force to a surface of a holding unit that holds the lens. The surface is parallel to the optical axis of the lens, and the force is applied from the direction orthogonal to the optical axis of the lens using a tool.

When a force is applied to a holding unit that holds an optical element such as a lens using a tool, as in Japanese Patent Application Laid-Open No. 2004-219608, the holding unit may sometimes be uplifted or inclined. When such an unintended position change of the holding unit occurs, the position of the optical element cannot be adjusted.

### SUMMARY

The present disclosure is directed to providing a holding apparatus that can adjust the position of an optical element.

An aspect of the present disclosure provides a holding apparatus that includes a first holding unit configured to hold a first optical element, a second holding unit configured to hold a second optical element, the second holding unit being stacked on the first holding unit, and a lens barrel that accommodates the first holding unit and the second holding unit, the lens barrel including a support surface supporting the first holding unit. The first holding unit has a first surface at a position facing the lens barrel, the first surface being inclined with respect to an optical axis of the first optical element. The second holding unit has a second surface at a position facing the lens barrel, the second surface being inclined with respect to an optical axis of the second optical element. The lens barrel includes a first through-hole that is provided at a position corresponding to the first surface and extends in a first direction orthogonal to the optical axis of the first optical element, and a second through-hole that is provided at a position corresponding to the second surface and extends in a second direction orthogonal to the optical axis of the second optical element.

Further features of the present disclosure will become apparent from the following description of exemplary embodiments with reference to the attached drawings.

### BRIEF DESCRIPTION OF THE DRAWINGS

FIG. 1 is a schematic diagram illustrating a configuration of a substrate processing apparatus according to a first exemplary embodiment.

FIG. 2 is a cross-sectional diagram of an objective lens included in a detection unit according to the first exemplary embodiment.

FIGS. 3A, 3B, 3C, and 3D are diagrams illustrating an example of assembly of the objective lens according to the first exemplary embodiment.

FIG. 4 is a schematic diagram illustrating application of a force to a first holding unit by a first adjustment unit.

FIG. 5 is a flowchart of a method for manufacturing an objective lens according to the first exemplary embodiment.

FIGS. 6A and 6B are plan views of the first holding unit viewed from a +Z direction side of the first holding unit.

FIG. 7 is a diagram illustrating a detection unit according to the first exemplary embodiment.

FIG. 8 is a schematic diagram illustrating a configuration of a measurement apparatus according to the first exemplary embodiment.

FIG. 9 is a cross-sectional diagram of an objective lens included in a detection unit according to a second exemplary embodiment.

FIG. 10 is a cross-sectional diagram of an objective lens included in a detection unit according to a third exemplary embodiment.

FIGS. 11A and 11B are cross-sectional diagrams of an objective lens included in a detection unit according to a fourth exemplary embodiment.

FIG. 12 is a diagram illustrating a flowchart of a method for manufacturing a product.

FIG. 13 is a cross-sectional diagram of an objective lens included in a conventional detection unit.

FIGS. 14A to 14D are diagrams illustrating an example of assembly of a conventional objective lens.

### DETAILED DESCRIPTION

Hereinafter, exemplary embodiments of the present disclosure will be described with reference to the drawings. The following exemplary embodiments do not limit the disclosure according to the appended claims. Although a plurality of features is described in the exemplary embodiments, not all of the features are necessarily essential to the disclosure, and the exemplary embodiments may be freely combined. In the drawings, the same or similar components are denoted by the same reference numerals, and redundant description thereof will be omitted.

In the specification and the drawings, directions are basically indicated by an XYZ coordinate system in which the vertical direction is the Z-axis direction, a horizontal plane perpendicular to the vertical direction is the XY plane, and the axes are orthogonal to each other. However, in a case where an XYZ coordinate system is described in each drawing, the coordinate system is prioritized.

Hereinafter, a specific configuration will be described in each exemplary embodiment.

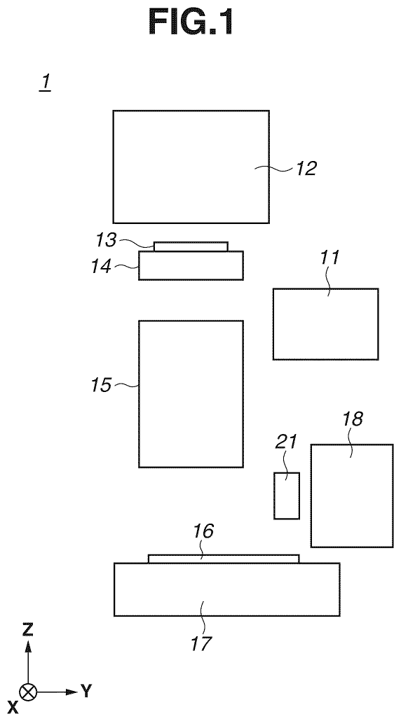

FIG. 1 is a schematic diagram illustrating a configuration of a substrate processing apparatus (exposure apparatus) 1 according to a first exemplary embodiment. In the present exemplary embodiment, the substrate processing apparatus 1 is a projection exposure apparatus that projects a pattern of an original (mask, reticle) to a substrate via a projection optical system using a step-and-repeat method or step-and-scan method.

The substrate processing apparatus 1 includes an illumination optical system 12 that emits light, a projection optical system 15, a reticle stage 14 that can move a reticle 13 while holding the reticle 13, a substrate stage 17 that can move a substrate 16 while holding the substrate 16, a temperature control device 18, a control unit 11, and a detection unit 21. The reticle 13 is, for example, an original in which a pattern (e.g., a circuit pattern) to be transferred is formed on a surface of quartz glass with chrome. The substrate 16 is, for example, monocrystalline silicon, and a photosensitive material (resist) is applied to the surface of the substrate 16 conveyed in the substrate processing apparatus 1 in a case where the substrate processing apparatus 1 is an exposure apparatus.

In the substrate processing apparatus 1, exposure light from a light source illuminates the reticle 13 held by the reticle stage 14, via the illumination optical system 12. Light having passed through the reticle 13 is emitted to the substrate 16 via the projection optical system 15. At the time, light from the pattern formed in the reticle 13 forms an image on the surface of the substrate 16, and a shot region is exposed to light of a pattern image on the substrate 16 (photosensitive material). The substrate processing apparatus 1 exposes the shot region on the substrate 16 in this manner, and similarly performs exposure for each of a plurality of shot regions.

When exposure processing is performed on the substrate 16, the control unit 11 performs control to adjust relative positions of the substrate 16 and the reticle 13 based on a result of the detection unit 21 detecting the position of at least one of an alignment mark of the substrate 16 and an alignment mark of the substrate stage 17. The detection unit 21 includes, for example, a light source and an objective lens including a plurality of optical elements.

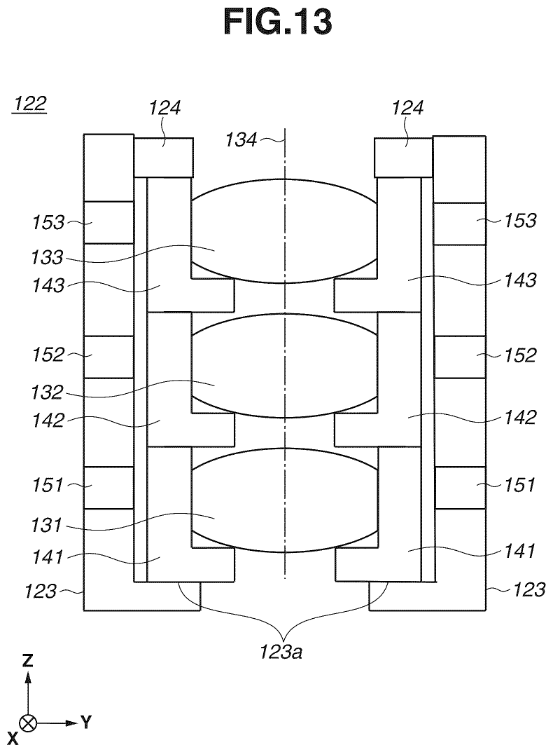

FIG. 13 is a cross-sectional diagram of an objective lens 122 included in a conventional mark detection unit. The objective lens 122 includes a first optical element 131, a second optical element 132, and a third optical element 133 inside a lens barrel 123. The first optical element 131, the second optical element 132, and the third optical element 133 are respectively held by a first holding unit 141, a second holding unit 142, and a third holding unit 143. In the lens barrel 123, a first through-hole 151 is provided at a position corresponding to the first holding unit 141, a second through-hole 152 is provided at a position corresponding to the second holding unit 142, and a third through-hole 153 is provided at a position corresponding to the third holding unit 143.

FIG. 13 illustrates a state in which relative positions of the first optical element 131, the second optical element 132, and the third optical element 133 are correctly adjusted, and the position of an optical axis of each optical element coincides with the position of an optical axis 134 of the objective lens 122. A holding unit group including the plurality of holding units is pressed with a retainer collar 124 positioned above the plurality of holding units, so that the relative positions of the first optical element 131, the second optical element 132, and the third optical element 133 do not change. In other words, the position of the holding unit group including the plurality of holding units is fixed by being sandwiched between the retainer collar 124 and a support surface 123a that supports the first holding unit 141 of the lens barrel 123. The position of an optical axis in the present exemplary embodiment refers to the position of an optical axis on an XY-plane orthogonal to a direction parallel to the optical axis (Z-axis direction) in an XY Z coordinate system.

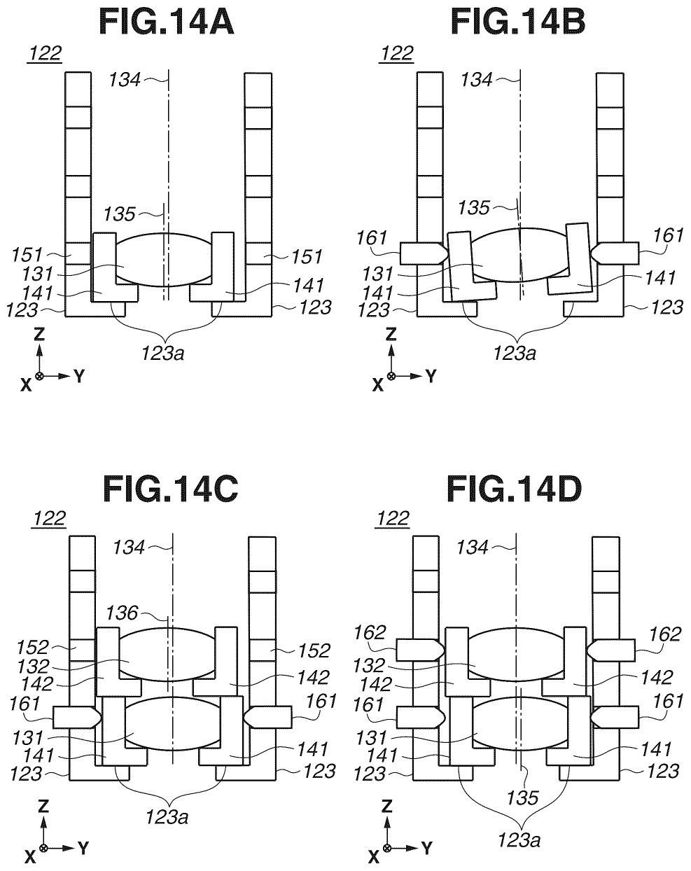

FIGS. 14A to 14D are diagrams illustrating an example of assembly of the conventional objective lens 122. FIG. 14A illustrates a state in which the first holding unit 141 holding the first optical element 131 is supported by the support surface 123a. At the time, the position of an optical axis 135 of the first optical element 131 is shifted from the position of the optical axis 134. FIG. 14B illustrates an example of adjusting the position of the first optical element 131 in a direction orthogonal to a direction parallel to the optical axis 135 of the first optical element 131 by inserting a first adjustment unit 161 into the first through-hole 151 and applying a force to the side surface of the first holding unit 141 with the first adjustment unit 161. When a force is applied to the first holding unit 141 with the first adjustment unit 161, the first holding unit 141 may at times incline, as illustrated in FIG. 14B. Because the first optical element 131 also inclines by the first holding unit 141 inclining, the optical axis 135 inclines with respect to (no longer coincides with) the optical axis 134. In addition, when a force is applied to the first holding unit 141 with the first adjustment unit 161, the first holding unit 141 may at times be lifted off from the support surface 123a. Consequently, it may not be possible to correctly adjust the position of the first optical element 131. The inclination and uplift of such an optical element are more likely to occur as the weight of the optical element and the holding unit is reduced.

FIG. 14C illustrates a state in which the second holding unit 142 is placed on the first holding unit 141 after the first optical element 131 is correctly positioned. At this time, the position of an optical axis 136 of the second optical element 132 is shifted from the position of the optical axis 134. FIG. 14D illustrates an example of adjusting the position of the second optical element 132 in a direction orthogonal to a direction parallel to the optical axis 136 of the second optical element 132 by inserting a second adjustment unit 162 into the second through-hole 152 and applying a force to the second holding unit 142 with the second adjustment unit 162. By moving the second holding unit 142 by applying a force to the second adjustment unit 162 as illustrated in FIG. 14D, the position of the optical axis 136 of the second optical element 132 can be adjusted to coincide with the position of the optical axis 134. On the other hand, in some cases, the position of the first holding unit 141 being in contact with the second holding unit 142 may be shifted when the optical axis 136 is coincided with the optical axis 134, and the optical axis 135 of the first optical element 131 may be shifted from the position of the optical axis 134.

Shifting of the first holding unit 141 that is caused when the second holding unit 142 is moved may at times be solved by a method of fixing the position of the first holding unit 141 using a retainer collar after an adjustment of the position of the first holding unit 141 and arranging the second holding unit 142 on the retainer collar. Nevertheless, in this method, it takes time to arrange the retainer collar after the position adjustment of each holding unit.

Further, a space for providing the retainer collar between the two holding units, i.e., the upper and lower holding units, and the objective lens 122 is increased in size. Here, a space in which the mark detection unit is arranged is very small because the temperature control device 18 for stabilizing the temperature near the mark detection unit is arranged, for example. For this reason, the mark detection unit including the objective lens 122 may be small in size.

In view of the foregoing, in the present exemplary embodiment, a holding apparatus that can accurately adjust the position of an optical element by reducing the inclination and the uplift of an optical element that are caused when the position of the optical element is adjusted.

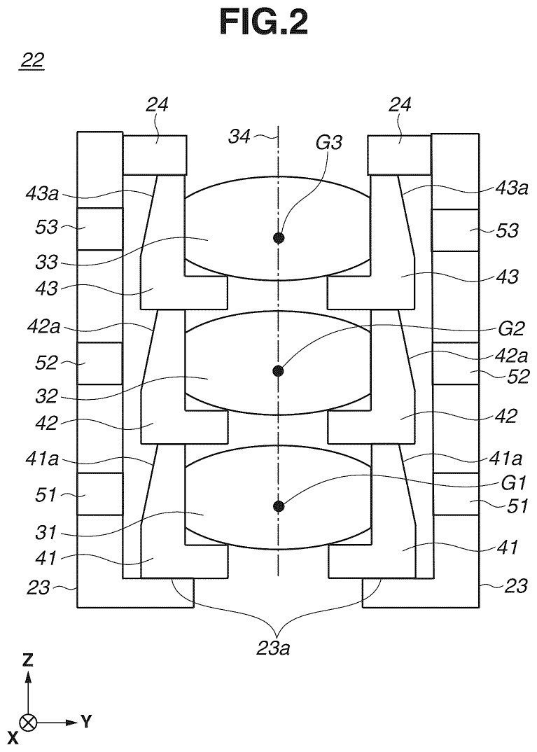

FIG. 2 is a cross-sectional diagram of an objective lens 22 included in the detection unit 21 according to the present exemplary embodiment.

In FIG. 2, the objective lens 22 includes a first optical element 31, a second optical element 32, and a third optical element 33 inside a lens barrel 23. The first optical element 31, the second optical element 32, and the third optical element 33 may be convex lenses (positive lenses) or concave lenses (negative lenses). The first optical element 31, the second optical element 32, and the third optical element 33 are respectively held by a first holding unit 41, a second holding unit 42, and a third holding unit 43. In other words, the lens barrel 23 accommodates the first optical element 31, the second optical element 32, the third optical element 33, the first holding unit 41, the second holding unit 42, and the third holding unit 43.

A center of gravity of the first holding unit 41 is center of gravity G1, a center of gravity of the second holding unit 42 is center of gravity G2, a center of gravity of the third holding unit 43 is center of gravity G3, with all of G1, G2, and G3 provided are on an optical axis.

The relative positions of the optical elements and the holding units are fixed using an adhesive agent, for example. When the adhesive agent has a small dimensional change before and after curing, for example, a distortion amount of the optical element becomes smaller. Alternatively, the adhesive agent may be an ultraviolet cure adhesive agent that does not cure until being irradiate with an ultraviolet ray and that enables an accurate adjustment of an adhesion position.

In the lens barrel 23, a plurality of first through-holes 51 is provided at positions corresponding to the first holding unit 41, a plurality of second through-holes 52 is provided at positions corresponding to the second holding unit 42, and a plurality of third through-holes 53 is provided at positions corresponding to the third holding unit 43. In addition, a first inclined surface 41a is provided in the first holding unit 41 at the position corresponding to each of the first through-holes 51, a second inclined surface 42a is provided in the second holding unit 42 at the position corresponding to each of the second through-holes 52, and a third inclined surface 43a is provided in the third holding unit 43 at the position corresponding to each of the third through-holes 53.

In other words, in the lens barrel 23, the first through-holes 51 are provided at the positions corresponding to the first inclined surface 41a of the first holding unit 41, the second through-holes 52 are provided at the positions corresponding to the second inclined surface 42a of the second holding unit 42, and the third through-holes 53 are provided at the positions corresponding to the third inclined surface 43a of the third holding unit 43.

The first inclined surface 41a, the second inclined surface 42a, and the third inclined surface 43a are positioned to face an inner wall of the lens barrel 23. The first through-holes 51 each extend along a first direction orthogonal to a direction parallel to an optical axis 35 of the first optical element 31. The second through-holes 52 each extend along a second direction orthogonal to a direction parallel to an optical axis 36 of the second optical element 32. The third through-holes 53 each extend along a third direction orthogonal to a direction parallel to an optical axis of the third optical element 33.

In the present exemplary embodiment, each of the through-holes 51 to 53 extends in the direction orthogonal to the direction parallel to the optical axis. Nevertheless, the direction in which each of the through-holes 51 to 53 extends may be slightly shifted from the direction orthogonal to the direction parallel to the optical axis as long as the direction extends in the direction orthogonal to the direction parallel to the optical axis and extends toward a corresponding inclined surface. In addition, the directions in which the through-holes 51 to 53 extend may not necessarily be the same, and a configuration in which a direction in which one through-hole extends differs from a direction in which the other two through-holes extend, or a configuration in which directions in which three through-holes extend differ from each other can be employed.

The first through-holes 51 are holes into each of which a first adjustment unit 61, described below, can be inserted and are provided one each on a +Y direction side and a −Y direction side of the lens barrel 23. By applying a force to the first holding unit 41 with the first adjustment unit 61 inserted into the first through-holes 51, the position of the first holding unit 41 may be adjusted in a Y-axis direction. The second through-holes 52 are holes into which a second adjustment unit 62, described below, can be inserted and are provided one each on the +Y direction side and the −Y direction side of the lens barrel 23. By applying a force to the second holding unit 142 with the second adjustment unit 62 inserted into the second through-holes 52, the position of the second holding unit 42 may be adjusted in the Y-axis direction. The third through-holes 53 are holes into which a third adjustment unit 63, described below, can be inserted and are provided one each on the +Y direction side and the −Y direction side of the lens barrel 23. By applying a force to the third holding unit 143 with the third adjustment unit 63 inserted into the third through-holes 53, the position of the third holding unit 43 may be adjusted in the Y-axis direction. In this manner, the first adjustment unit 61, the second adjustment unit 62, and the third adjustment unit 63 are components for adjusting the positions of the optical elements held by the corresponding optical element holding units in the direction orthogonal to the direction parallel to the optical axis.

FIG. 2 illustrates a state in which relative positions of the first optical element 31, the second optical element 32, and the third optical element 33 are correctly adjusted, and the optical axis of each of the optical elements coincides with an optical axis 34 of the objective lens 22. A holding unit group including the plurality of holding units is pressed with a retainer collar 24 from above so that the relative positions of the first optical element 31, the second optical element 32, and the third optical element 33 do not change. In other words, the position of the holding unit group including the plurality of holding units is fixed by being sandwiched between the retainer collar 24 and a support surface 23a that supports the first holding unit 41 of the lens barrel 23.

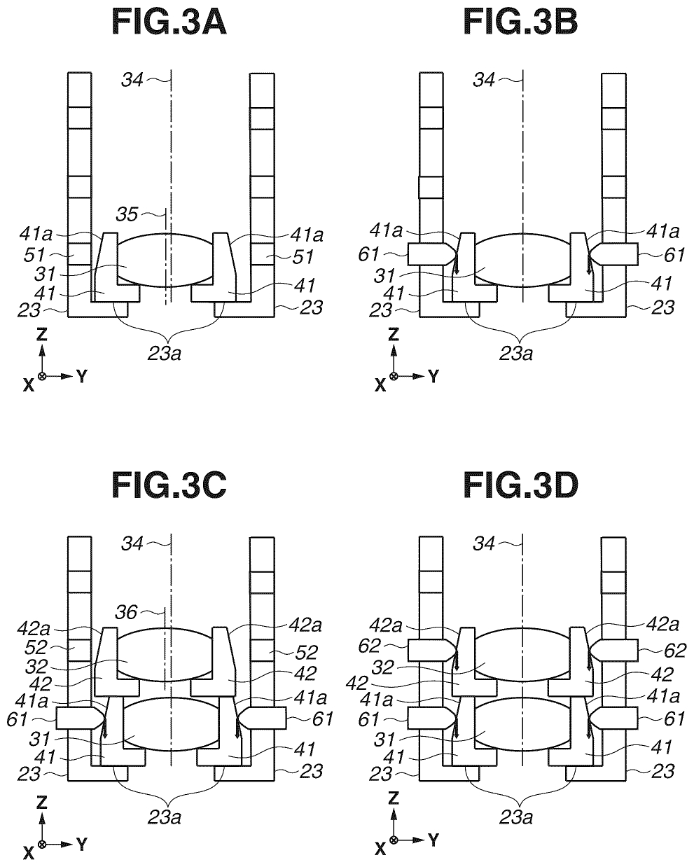

FIGS. 3A to 3D are diagrams illustrating an example of assembly of the objective lens 22 according to the present exemplary embodiment. FIG. 3A is a diagram illustrating a state in which the first holding unit 41 holding the first optical element 31 is supported by the support surface 23a. At this time, the position of the optical axis 35 of the first optical element 31 is shifted from the position of the optical axis 34.

FIG. 3B is a diagram illustrating an example of adjusting the position of the first optical element 31 in a direction orthogonal to a direction parallel to the optical axis 35 of the first optical element 31 by inserting first adjustment units 61 into the first through-holes 51 and applying forces to the first holding unit 41 with the first adjustment units 61. The adjustment is performed by applying a force using the first adjustment unit 61 on the −Y direction side to move the first holding unit 41 toward the +Y direction side. In accordance with the force applied with the first adjustment unit 61 on the −Y direction side, the first adjustment unit 61 on the +Y direction side is pressed by the first holding unit 41 and moves in the +Y direction.

The position adjustment of the first holding unit 41 (for the first optical element 31) according to the present exemplary embodiment is performed by the first adjustment unit 61 applying a force to the first inclined surface 41a. By the first adjustment unit 61 applying the force to the first inclined surface 41a, a force acts on the first holding unit 41 not only in a direction (the Y-axis direction) orthogonal to a direction parallel to the optical axis 35 of the first optical element 31, but also in a direction (−Z direction) toward the support surface 23a that is parallel to the optical axis 35 of the first optical element 31. In addition, the first adjustment unit 61 on the +Y direction side is in contact with the first inclined surface 41a on the +Y direction side, and the first holding unit 41 receives a force in the direction (−Z direction) toward the support surface 23a that is parallel to the optical axis 35 from the first adjustment unit 61 on the +Y direction side. Thus, a possibility that the inclination or the uplift of the first holding unit 41 occurs is reduced when a decentering adjustment of the optical axis 35 of the first optical element 31 is performed.

FIG. 3C is a diagram illustrating a state in which the second holding unit 42 holding the second optical element 32 is supported by the first holding unit 41. At this time, since the optical axis 35 of the first optical element 31 is adjusted by the first adjustment units 61, the position of the optical axis 35 coincides with the position of the optical axis 34. On the other hand, the position of the optical axis 36 of the second optical element 32 is shifted from the position of the optical axis 34.

FIG. 3D is a diagram illustrating an example of adjusting the position of the second optical element 32 in a direction orthogonal to a direction parallel to the optical axis 36 of the second optical element 32 by inserting second adjustment units 62 into the second through-holes 52 and applying forces to the second holding unit 42 with the second adjustment units 62. The adjustment is performed by applying a force using the second adjustment unit 62 on the −Y direction side to move the second holding unit 42 toward the +Y direction side. In accordance with the force applied with the second adjustment unit 62 on the −Y direction side, the second adjustment unit 62 on the +Y direction side is pressed by the second holding unit 42 and moves in the +Y direction.

The position adjustment of the second holding unit 42 holding the second optical element 32 according to the present exemplary embodiment is performed by the second adjustment unit 62 applying a force to the second inclined surface 42a. By the second adjustment unit 62 applying the force to the second inclined surface 42a, a force acts on the second holding unit 42 not only in the +Y direction orthogonal to a direction parallel to the optical axis 36 of the second optical element 32, but also in a direction (−Z direction) toward the first holding unit 41 that is parallel to the optical axis 36 of the second optical element 32. In addition, the second adjustment unit 62 on the +Y direction side is in contact with the second inclined surface 42a on the +Y direction side, and the second holding unit 42 receives a force in the direction (−Z direction) toward the first holding unit 41 that is parallel to the optical axis 36 from the second adjustment unit 62 on the +Y direction side. This can reduce a possibility that the inclination or the uplift of the second holding unit 42 occurs. Accordingly, the position of the second holding unit 42 may be adjusted in such a manner that the inclination or the uplift of the second holding unit 42 does not occur.

Conventionally, the position of the first holding unit 41, the position adjustment of which has been completed, has been shifted due to the position adjustment of the second holding unit 42. Nevertheless, in the present exemplary embodiment, since the first holding unit 41 is pressed against the support surface 23a by receiving the force in the −Z direction from the first adjustment unit 61, a possibility that the position of the first holding unit 41 may change is reduced during the position adjustment of the second holding unit 42. Accordingly, the position of the second holding unit 42 may be adjusted in such a manner that a position change of the first holding unit 41 does not occur. With this configuration, the position of the optical axis 35 of the first optical element 31 and the position of the optical axis 36 of the second optical element 32 may coincide with the position of the optical axis 34.

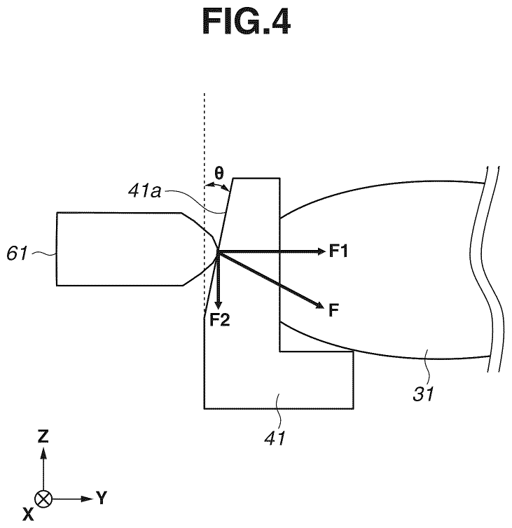

FIG. 4 is a schematic diagram illustrating application of a force to the first holding unit 41 by the first adjustment unit 61. Here, an inclination angle of the first inclined surface 41a of the first holding unit 41 with respect to a direction (the Z-axis direction) parallel to the optical axis is denoted by θ. The inclination angle θalso serves as an inclination angle with respect to the optical axis 35 of the first optical element 31.

In a case where the optical axis 35 of the first optical element 31 and the inner wall of the lens barrel 23 are parallel, the inclination angle also serves as an inclination angle with respect to the inner wall of the lens barrel 23. When the first adjustment unit 61 on the −Y direction side applies a force F to the first holding unit 41 toward the +Y direction side, the force F applied to the first inclined surface 41a is distributed in a direction (the Y-axis direction) orthogonal to a direction parallel to the optical axis and a direction (the Z-axis direction) parallel to the optical axis. The force F is distributed into a force F1 for pressing the first holding unit 41 that is applied in the Y-axis direction, and a force F2 for pressing the first holding unit 41 in the −Z direction that is applied in the Z-axis direction. The magnitude of the force F1 is represented by Equation (1) and the magnitude of the force F2 is represented by Equation (2):

$$F 1 = F cos θ \qquad ( 1 )$$

$$F 2 = F sin θ \qquad ( 2 )$$

In the present exemplary embodiment, to press an inclined surface during the position adjustment of a holding unit, a force in the −Z direction is applied to the holding unit (in the example illustrated q in FIG. 4, the force F2 is applied to the first holding unit 41). By the force F2, the inclination and the uplift of the first holding unit 41 may be reduced. The same applies to the second inclined surface 42a and the third inclined surface 43a.

An inclination angle of the inclined surface can be determined based on the relative positions of an adjustment unit and a holding unit when the adjustment unit applies a force to the holding unit, a center-of-gravity position of the holding unit, a friction coefficient of the holding unit, and the like. The inclination angle can be determined in the range of 0°<θ<90°. As the inclination angle becomes larger, the force F2 becomes larger.

The inclination angle may be in the range of 10°<θ<80°. The inclined surface may be provided such that the inclination and the uplift of the holding unit are reduced, i.e., such that a force acts on the holding unit toward the −Z direction side. Accordingly, a position on a surface pressed by the adjustment unit is closer to the optical axis of the optical element as the position is located more toward the +Z direction side. In other words, when the first holding unit 41 of the lens barrel 23 is supported by the support surface 23a and the first holding unit 41 supports the second holding unit 42, the first inclined surface 41a is an inclined surface that becomes closer in distance to the optical axis 35 of the first optical element 31 as a position thereon is away from the support surface 23a. In addition, the second inclined surface 42a is an inclined surface that becomes closer in distance to the optical axis 36 of the second optical element 32 as a position thereon is away from the support surface 23a.

A position in each holding unit where the inclined surface is provided is a position corresponding to the center of gravity of the holding unit. Thus, at least one of positions in the Z-axis direction of the inclined surface matches the position in the Z-axis direction of the center of gravity of the holding unit. The center-of-gravity position of each holding unit can be acquired from design information. By the adjustment unit pressing the position corresponding to the center of gravity of the holding unit, the inclination of the holding unit may be further reduced. For example, by the adjustment unit pressing a position in the Z-axis direction that is the same as the above-described center of gravity among positions on the inclined surface of the holding unit, the inclination of the holding unit may be further reduced.

As described above, in the present exemplary embodiment, the holding unit includes the inclined surface inclined with respect to the optical axis of the optical element. For example, the first holding unit 41 includes the inclined surface inclined with respect to the optical axis 35 of the first optical element 31, and the second holding unit 42 includes the inclined surface inclined with respect to the optical axis 36 of the second optical element 32.

A position adjustment amount of the holding unit (optical element) is determined based on, for example, a measurement result obtained by a measuring device. The measuring device measures, for example, a focal position on each surface of the optical element and calculates a shift of the optical axis of the optical element from a reference position (the optical axis 34) based on the measurement result. The measuring device is, for example, OptiCentric of Trioptics Japan Co., Ltd..

An adjustment unit is, for example, a plunger that includes a spring therein and can perform alignment. Alternatively, the adjustment unit may be a rod-like member not including a spring, or a screw. An adjustment unit provided at a position opposing an adjustment unit pressing the holding unit is pressed by the holding unit. At this time, the holding unit receives a force in a direction (the −Z direction) parallel to the optical axis of the optical element held by the holding unit, from the adjustment unit, and in a case where the adjustment unit is a plunger including a spring, a force in the −Z direction is further applied to the holding unit by a spring force. Thus, in the case where the adjustment unit is a plunger that includes a spring, the inclination and the uplift of the holding unit may be further reduced. The through-hole into which the adjustment unit is inserted may be a female screw, and the adjustment unit may be a male screw. A tip portion of the adjustment unit may have a ball shape or a pin shape, and the shape thereof is not limited thereto. In the present exemplary embodiment, as illustrated in FIG. 3, by the adjustment unit applying a force to an inclined portion included in the holding unit, a positional shift of the holding unit (optical element) that occurs during the position adjustment may be reduced.

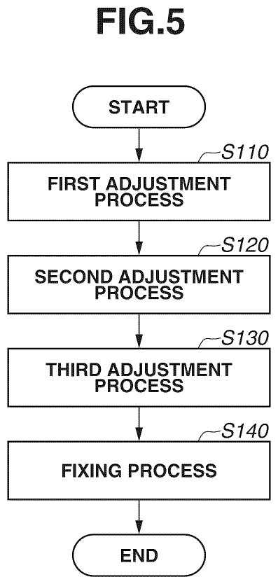

FIG. 5 is a flowchart of a method for manufacturing the objective lens (optical device) 22 according to the present exemplary embodiment illustrated in FIG. 2. In step S110, a first adjustment process is performed that includes applying a force to the first inclined surface 41a of the first holding unit 41 with the first adjustment unit 61, the position of the first holding unit 41 (the first optical element 31) being adjusted such that the position of the optical axis 35 of the first optical element 31 held by the first holding unit 41 coincides with the position of the optical axis 34. The adjustment of the position is an adjustment of the position of the first optical element 31 in the direction orthogonal to the direction parallel to the optical axis 35 of the first optical element 31.

Next, in step S120, a second adjustment process is performed that includes the second holding unit 42 holding the second optical element 32 being placed on the first holding unit 41, and the position of the second holding unit 42 in the direction orthogonal to the direction parallel to the optical axis 36 being adjusted. In the adjustment, by applying a force to the second inclined surface 42a of the second holding unit 42 with the second adjustment unit 62, the position of the second holding unit 42 (the second optical element 32) is adjusted such that the position of the optical axis 36 of the second optical element 32 held by the second holding unit 42 coincides with the position of the optical axis 34.

In other words, the adjustment of the position is an adjustment of the position of the second optical element 32 in the direction orthogonal to the direction parallel to the optical axis 36 of the second optical element 32.

Next, in step S130, a third adjustment process is performed that includes the third holding unit 43 holding the third optical element 33 being placed on the second holding unit 42, and the position of the third holding unit 43 in the direction orthogonal to the direction parallel to the optical axis being adjusted. In the adjustment, by applying a force to the third inclined surface 43a of the third holding unit 43 with the third adjustment unit 63, the position of the third holding unit 43 (the third optical element 33) is adjusted such that the position of the optical axis of the third optical element 33 held by the third holding unit 43 coincides with the position of the optical axis 34. In other words, the adjustment of the position is an adjustment of the position of the third optical element 33 in the direction orthogonal to the direction parallel to the optical axis of the third optical element 33.

Next, in step S140, a fixing process is performed in a state in which the positions of the first optical element 31, the second optical element 32, and the third optical element 33 are adjusted, with the positions of the first optical element 31, the second optical element 32, and the third optical element 33 being fixed with the retainer collar 24. After the fixing process is executed, each of the adjustment units may be removed from each of the through-holes. Each of the through-holes from which the adjustment unit is removed may be closed by inserting an object or may not be closed.

In the present exemplary embodiment, the example is described in which the objective lens 22 includes three optical elements and three adjustment processes (the first adjustment process, second adjustment process, and third adjustment process) are performed since an adjustment process is performed on each of the optical elements, but the present exemplary embodiment is not limited to this example. For example, the objective lens 22 is to include one or more optical elements and one or more holding units, and the number of optical elements and the number of holding units can be one, two, three, or four or more in some cases. In addition, the first holding unit 41 and the second holding unit 42 included in the objective lens 22 are to include inclined surfaces inclined with respect to the optical axes of the first optical element 31 and the second optical element 32, respectively.

In the present exemplary embodiment, an example in which the retainer collar 24 is arranged to be in contact with the third optical element 33 (uppermost optical element) has been described, but an elastic member may be interposed between the retainer collar 24 and the uppermost optical element. By interposing the elastic member, a position change of each of the optical elements may be reduced when the optical elements are pressed with the retainer collar 24 from above. The elastic member is, for example, a wave washer or a Gore sheet. The fixing process need not be performed after adjustment processes for all the optical elements have been performed. For example, in a case where the first adjustment process and the second adjustment process are executed, and subsequently the third optical element 33 is installed, the third optical element 33 can be installed with high positional accuracy in some cases. This is because the third optical element 33 is installed in an upper layer of the lens barrel 23 where an installation operation can be performed. In such a case, even when an adjustment process has not been performed on the third optical element 33, the fixing process for fixing the positions of the first optical element 31, the second optical element 32, and the third optical element 33 may be performed. In other words, the position adjustment need not be performed on all the holding units (optical elements), and the position adjustment may be performed on a specific holding unit (optical element) included in the objective lens 22. For example, only the first adjustment process and the second adjustment process may be performed as the adjustment processes.

In the present exemplary embodiment, an example in which the positions of optical axes with which the positions of optical axes of all the optical elements included in the objective lens 22 are to be coincided are the same has been described, but the present exemplary embodiment is not limited to this example. The positions of the optical axes of the optical elements included in the objective lens 22 may be different from each other. The position of the optical axis of the first optical element 31 and the position of the optical axis of the second optical element 32 may be different from each other. While, in the present exemplary embodiment, an example in which the position of the optical axis of each of the optical elements is coincided with the position of the optical axis has been described, the position of the optical axis need not coincide with the position of the optical axis, and an adjustment may be performed so that the position of the optical axis of each of the optical elements falls within an allowable range.

In the present exemplary embodiment, an example in which neighboring holding units are in contact has been described, but the present exemplary embodiment is not limited to this example. For example, the first holding unit 41 and the second holding unit 42 may not be in contact due to a member provided between the first holding unit 41 and the second holding unit 42. In the present exemplary embodiment, an example of position adjustment of a holding unit (optical element) in the Y-axis direction has been described, but the present exemplary embodiment is not limited to this example. The position adjustment may be a position adjustment in a direction parallel to a plane (the XY-plane) orthogonal to a direction (the Z-axis direction) parallel to an optical axis of the optical element. For example, the position adjustment of each of the holding units (each of the optical elements) in an X-axis direction may be performed by providing a pair of through-holes, through which adjustment units are inserted in the X-axis direction, near the inclined surface of each of the holding units of the lens barrel 23 in such a manner that the through-holes oppose each other. Alternatively, by providing a through-hole around the central axis (the optical axis 34) of the lens barrel 23 at an interval of a predetermined angle, the position adjustment of the holding units (optical elements) in a plurality of directions parallel to the XY-plane may be performed. For example, four through-holes may be provided surrounding the central axis at an interval of 90 degrees, and the position adjustment of the holding unit (optical element) in the X-axis direction and the Y-axis direction may be performed using four adjustment units, for example. In other words, by providing the plurality of through-holes around the central axis at an interval of the predetermined angle and by using the adjustment units, the position adjustment of the holding unit (optical element) may be performed. The lens barrel 23 may include a fourth through-hole (first through-hole) that is provided at a position corresponding to the first inclined surface 41a and extends along a fourth direction (the X-axis direction) orthogonal to the optical axis 35 of the first optical element 31 different from the first direction (the Y-axis direction). The lens barrel 23 may include a fifth through-hole (second through-hole) that is provided at a position corresponding to the second inclined surface 42a and extends along a fifth direction (the X-axis direction) orthogonal to the optical axis 36 of the second optical element 32 different from the second direction (the Y-axis direction).

In the present exemplary embodiment, an example in which a shift of the optical axis of the optical element is obtained using the above-described measuring device and an adjustment is performed so that the position of the optical axis of the optical element coincides with the position of the optical axis has been described, but the present exemplary embodiment is not limited to this example. For example, the position adjustment of the optical element (holding unit) may be performed based on a measurement result obtained by measuring a relative position of the optical element (holding unit) relative to the position of the lens barrel 23, with the relative position of the optical element (holding unit) relative to a predefined position of the lens barrel 23 as a reference (target).

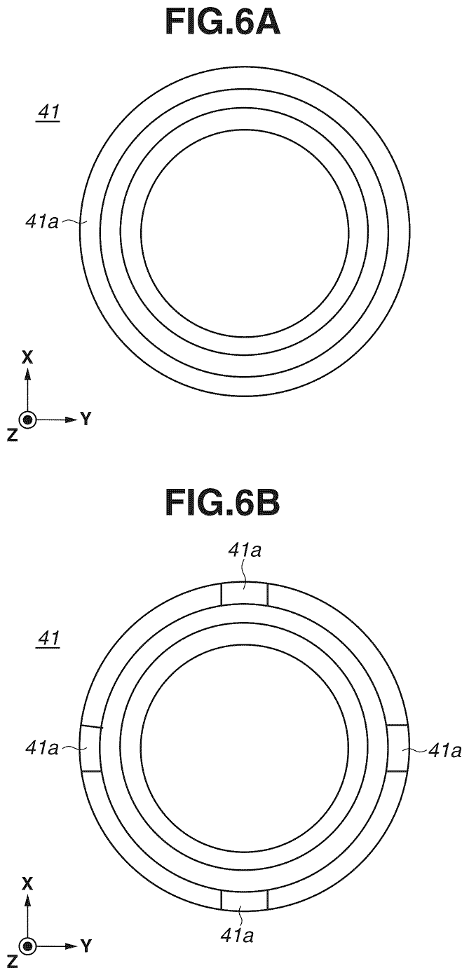

FIGS. 6A and 6B are plan views of the first holding unit 41 viewed from the +Z direction side of the first holding unit 41. As illustrated in FIG. 6A, the first inclined surface 41a may be provided over the entire circumference of the first holding unit 41. Alternatively, as illustrated in FIG. 6B, first inclined surfaces 41a may be selectively provided, for example provided only at four positions corresponding to four first through-holes 51 of the first holding unit 41. In the case of the configuration illustrated in FIG. 6B, the outer circumference of the first holding unit 41 includes four surfaces parallel to, for example, the optical axis 35 of the first optical element 31 each between neighboring inclined surfaces. The configuration described above and illustrated in FIGS. 6A and 6B may apply to the other holding units (the second holding unit 42, the third holding unit 43, or the like), and the number of first through-holes 51 is not limited to four.

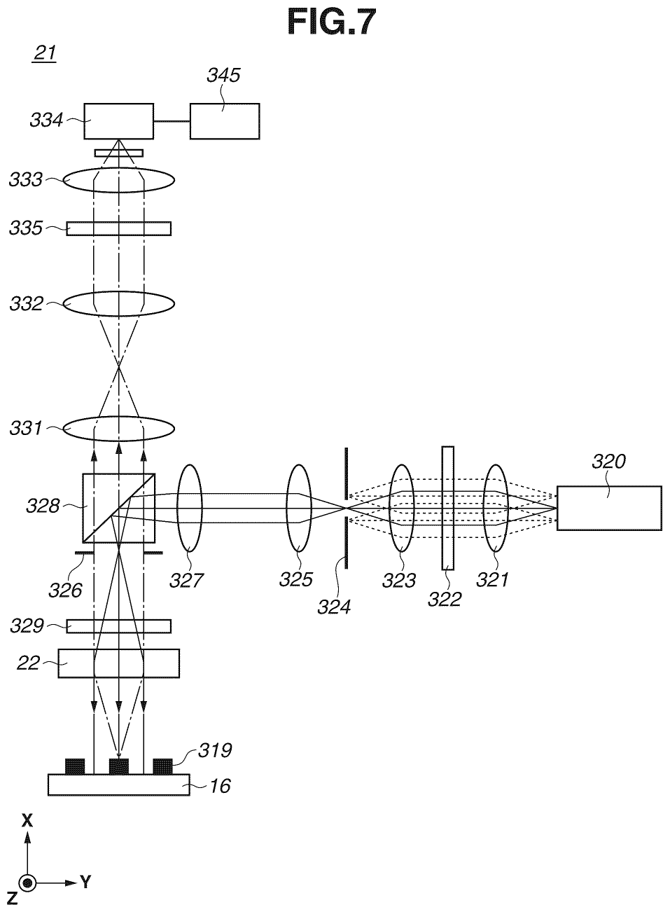

FIG. 7 is a diagram illustrating the detection unit 21 according to the present exemplary embodiment. Generally, the detection unit 21 is divided roughly into two detection systems, namely, an off-axis alignment (OA) detection system and through-the-lens alignment (TTL) detection system. The OA detection system optically detects an alignment mark 319 formed on the substrate 16 using light (non-exposure light) with a wavelength different from a wavelength of exposure light, rather than via a projection optical system. In the example illustrated in FIG. 7, an example in which the detection unit 21 is an OA detection system is illustrated, but this is not intended to limit a detection method of alignment.

The detection unit 21 includes a light source 320, a first relay optical system 321, a wavelength filter plate 322, a second relay optical system 323, an aperture stop 324, a first illumination system 325, a second illumination system 327, and a polarization beam splitter 328. The detection unit 21 further includes a diaphragm 326, a quarter wave plate 329, the objective lens 22 described in the present exemplary embodiment, a relay lens 331, a first imaging system 332, a coma aberration adjustment optical member 335, a second imaging system 333, a photoelectric conversion element 334, and a processing unit 345. Light from the light source 320 passes through the first relay optical system 321, the wavelength filter plate 322, and the second relay optical system 323, and reaches the aperture stop 324. The light having reached the aperture stop 324 is guided to the polarization beam splitter 328 via the first illumination system 325 and the second illumination system 327. Among light rays guided to the polarization beam splitter 328, S-polarized light vertical to the sheet surface is reflected by the polarization beam splitter 328 and is converted into circularly-polarized light through the diaphragm 326 and the quarter wave plate 329. Light having passed through the quarter wave plate 329 passes through the objective lens 22, and illuminates the front surface side mark (alignment mark) 319 formed on the substrate 16.

Reflected light, diffracted light, and scattered light from the front surface side mark 319 pass through the objective lens 22, are transmitted through the quarter wave plate 329, converted into P-polarized light parallel to the sheet surface, and is transmitted through the polarization beam splitter 328 via the diaphragm 326. Light having passed through the polarization beam splitter 328 forms an image of the front surface side mark 319 on the photoelectric conversion element (for example, a sensor such as a charge-coupled device (CCD) image sensor) 334 via the relay lens 331, the first imaging system 332, the coma aberration adjustment optical member 335, and the second imaging system 333. The photoelectric conversion element 334 captures (detects) the image of the front surface side mark 319 and acquires a detection signal. The processing unit 345 performs processing of obtaining the position of the mark based on the image of the mark captured by the photoelectric conversion element 334. The function of the processing unit 345 may be included in a control apparatus provided outside the detection unit 21.

In a case where the objective lens (optical device) 22 is manufactured using a holding apparatus of the present exemplary embodiment, a positional shift of the optical axis of the optical element with respect to the optical axis can be set to 3 μm or less, and the inclination of the optical axis of the optical element with respect to the optical axis can be set to ten seconds or less. By using the objective lens 22 in which the positional shift of the optical element is reduced as described above, an error in detecting (measuring) the position of a mark (alignment mark) in an exposure apparatus may be reduced. By using the objective lens 22, an error in detecting (measuring) the position of a mark (alignment mark) by about 30% compared with a conventional objective lens 122 may be reduced.

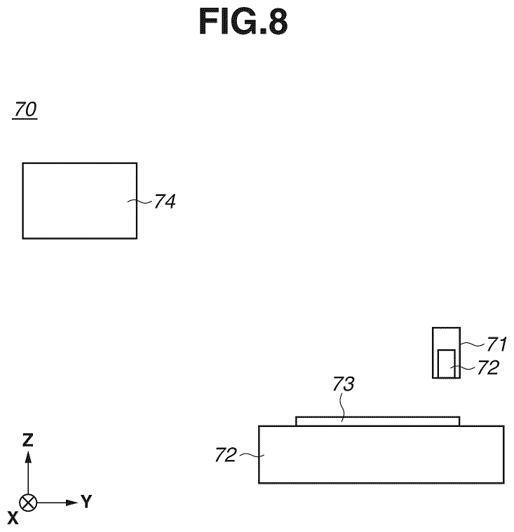

In the present exemplary embodiment, an example of the exposure apparatus including the detection unit 21 including the objective lens (optical device) 22 has been described, and the present exemplary embodiment is also applicable to an optical device configured as a part of another apparatus. For example, the present exemplary embodiment may be applied to the objective lens (optical device) 22 included in a detection unit 71 configured as a part of a measurement apparatus 70 illustrated in FIG. 8.

The measurement apparatus 70 includes the detection unit 71 including the objective lens 22, a substrate stage 72 that can move a substrate 73 while holding the substrate 73, and a control unit 74. The detection unit 71 has a configuration and a function similar to those of the above-described detection unit 21, and the substrate stage 72 has a configuration and a function similar to those of the above-described substrate stage 17. For conciseness, descriptions thereof are incorporated by reference without being repeated. The measurement apparatus 70 is an apparatus that measures the position of at least one of a mark (alignment mark) of a plurality of shot regions of the substrate 73, such as a semiconductor wafer, and a mark (alignment mark) of the substrate stage 72.

Position information on the alignment mark measured by the measurement apparatus 70 may be transmitted to a substrate processing apparatus (for example, an exposure apparatus), may be transmitted to an external information processing apparatus, or may be transmitted to a server, by the control unit 74. In addition, at least one of array information on a plurality of shots, shot magnification information, and wafer magnification information may be calculated by the measurement apparatus 70 or the control unit 74 based on the position information on the alignment mark. A calculation result (information) may be transmitted to the above-described substrate processing apparatus, the external information processing apparatus, or the server.

As an apparatus including an optical device to which the present exemplary embodiment is applicable may include a drawing apparatus that forms a pattern on a substrate by performing drawing on the substrate using an electron beam or an ion beam, and an imprinting apparatus that forms a pattern on a substrate by molding an imprinting material on the substrate using a mold. Alternatively, the present exemplary embodiment may be applied to an optical device formed as a part of another apparatus that processes a substrate such as a semiconductor wafer or a glass plate, such as an ion implantation apparatus, a development apparatus, an etching apparatus, a film formation apparatus, an annealing apparatus, a sputtering apparatus, and a deposition apparatus. Alternatively, the present exemplary embodiment may be applied to an optical device configured as a part of a planarization apparatus that planarizes a composition on a substrate using a flat plate.

As described above, according to the present exemplary embodiment, since the inclination and the uplift of a holding unit (optical element) that occur during a position adjustment of the holding unit (optical element) can be reduced, the position of the optical element may be accurately adjusted.

In the first exemplary embodiment, the inclination angle of the first inclined surface 41a, the inclination angle of the second inclined surface 42a, and the inclination angle of the third inclined surface 43a are the same. In a second exemplary embodiment, an inclination angle of a first inclined surface 41b, an inclination angle of a second inclined surface 42b, and an inclination angle of a third inclined surface 43b differ from each other.

For example, in an objective lens 22 with a large magnification, in some cases, an optical element on a lower side (the −Z direction side) may be smaller. In the case of adjusting the position of a holding unit for holding such a small-sized optical element, because such a small-sized optical element is more lightweight than a large-sized optical element, the inclination and the uplift of the holding unit are likely to occur. In addition, a holding unit on a lower side (the −Z direction side) in the objective lens 22 is more likely to be affected by position adjustments of a plurality of stacked holding units. There is a possibility that a positional shift of the lowermost first holding unit 41 occurs due to influences of the position adjustment of the second holding unit 42 and the position adjustment of the third holding unit 43 that are provided above.

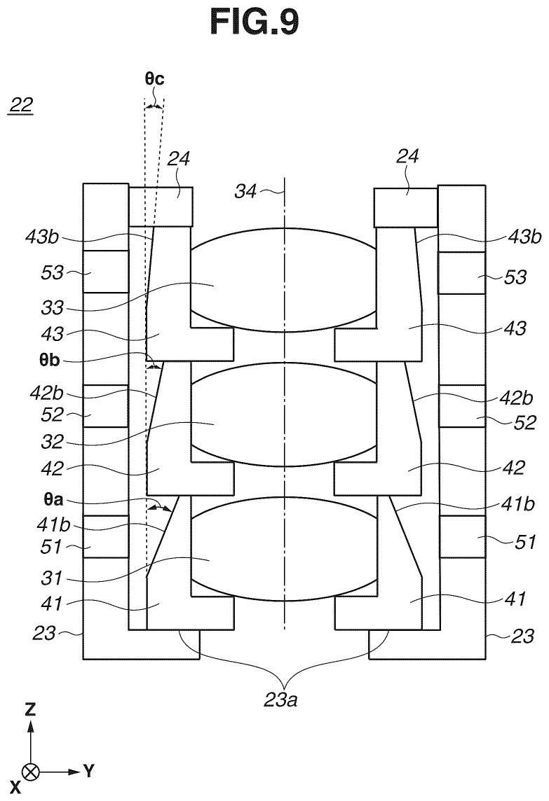

To reduce the possibility, in the present exemplary embodiment, the inclination angles of the inclined surfaces included in the plurality of holding units are made different. FIG. 9 is a cross-sectional diagram of the objective lens 22 included in the detection unit 21 according to the present exemplary embodiment. When the inclination angle of the first inclined surface 41b is described as a first inclination angle θa, the inclination angle of the second inclined surface 42b is described as a second inclination angle θb, and the inclination angle of the third inclined surface 43b is described as a third inclination angle θc, a relationship of magnitude of the inclination angles is θa>θb>θc. The larger the inclination angle is, the larger the force acting on the holding unit toward the lower side (the −Z direction side) is. Thus, in a case where a force is applied with the adjustment unit with the same magnitude of force, a larger force toward the lower side (the −Z direction side) is received by the first holding unit 41, the second holding unit 42, and the third holding unit 43 in this order. In a case where the force F in the Y-axis direction orthogonal to a direction parallel to a direction (the Z-axis direction) parallel to an optical axis is applied to each of the holding units, a force toward the −Z direction side that is applied to the first holding unit 41 may be denoted by Fa, a force toward the −Z direction side that is applied to the second holding unit 42 may be denoted by Fb, and a force toward the −Z direction side that is applied to the third holding unit 43 may be denoted by Fc. In this case, a relationship of magnitude of the forces is Fa>Fb>Fc.

The inclination and the uplift of the holding unit (optical element) may be reduced by increasing the inclination angle of the inclined surface of the holding unit also in a case where the position of the holding unit holding a small-sized optical element is adjusted. Also, a positional shift of the holding unit on the lower side (the −Z direction side) due to the adjustment of the position of the holding unit stacked thereon may be reduced.

In the present exemplary embodiment, an example in which the inclination angles of the inclined surfaces of three optical elements are made different from each other has been described, but the present exemplary embodiment is not limited to this example. The number of optical elements is to be two or more, and in a case where the number of optical elements is four, for example, the inclination angles of the inclined surfaces of holding units may be made different from each other so that an inclination angle of an inclined surface of a holding unit in a lower layer (in the −Z direction in the present exemplary embodiment) is larger. Alternatively, all the inclination angles of the inclined surfaces of the holding units included in the objective lens 22 may not be made different from each other. For example, the inclination angle of the first inclined surface 41b of the first holding unit 41 may be made larger than the inclination angle of the second inclined surface 42b of the second holding unit 42, and the inclination angle of the second inclined surface 42b of the second holding unit 42 and the inclination angle of the third inclined surface 43b of the third holding unit 43 may be made equal. In other words, the inclination angles of the inclined surfaces of at least two holding units of the plurality of holding units included in the objective lens 22 may be made different from each other. In addition, in the present exemplary embodiment, while the inclination angle of the inclined surface included in the holding unit on the lower side (the −Z direction side) is made larger, the inclination angle of the inclined surface included in the holding unit on the upper side (+Z direction side) may be made larger.

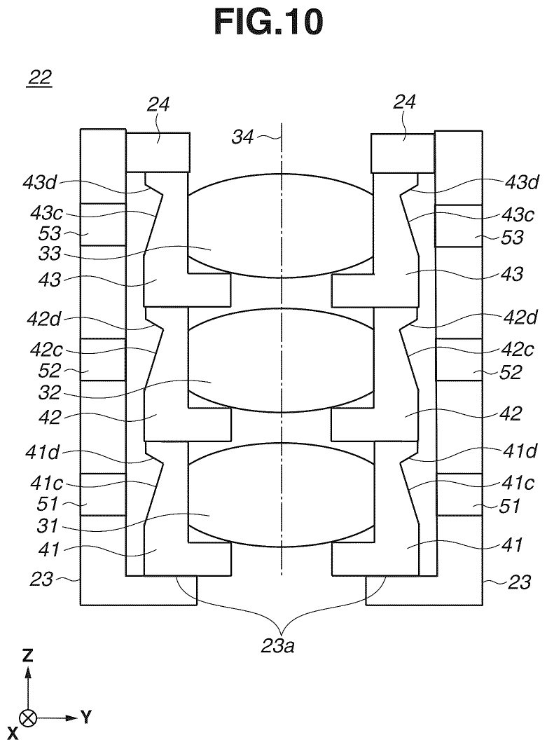

In a third exemplary embodiment, the shape of a holding unit differs from that in the first exemplary embodiment and second exemplary embodiment. The holding unit according to the present exemplary embodiment includes a V-shaped groove having two inclined surfaces inclined with respect to the optical axis of an optical element held by the holding unit, and a part of the V-shaped groove serves as an inclined surface to which a force is to be applied by the adjustment unit. FIG. 10 is a cross-sectional diagram of an objective lens 22 included in a detection unit 21 according to the present exemplary embodiment. The first holding unit 41 includes a first inclined surface 41c at a position corresponding to a first through-hole 51 and includes a first inclined surface 41d inclined in a direction different from an inclination direction of the first inclined surface 41c, on the +Z direction side of the first inclined surface 41c. The second holding unit 42 includes a second inclined surface 42c at a position corresponding to a second through-hole 52 and includes a second inclined surface 42d inclined in a direction different from an inclination direction of the second inclined surface 42c, on the +Z direction side of the second inclined surface 42c. The third holding unit 43 includes a third inclined surface 43c at a position corresponding to a third through-hole 53 and includes a third inclined surface 43d inclined in a direction different from an inclination direction of the third inclined surface 43c, on the +Z direction side of the third inclined surface 43c.

The first inclined surface 41c, the second inclined surface 42c, and the third inclined surface 43c correspond to the positions of the through-holes into which the adjustment units are to be inserted, and as in the above-described exemplary embodiment, a force toward the −Z direction side acts on each of the holding units. With this configuration, the inclination and the uplift of each of the holding units may be reduced when a force is applied to the holding unit for position adjustment. By providing the first inclined surface 41d, an area of a surface on which the first holding unit 41 supports the second holding unit 42 and to stably support the second holding unit 42 may be increased. As with the first inclined surface 41d, the second inclined surface 42d and the third inclined surface 43d can obtain an effect of stably supporting a holding unit and a retainer collar that are provided thereon. The inclination angles of the first inclined surface 41c and the second inclined surface 42c in the present exemplary embodiment may be made different from each other. In the present exemplary embodiment, an example in which the V-shaped grooves are provided in both the first holding unit 41 and the second holding unit 42 has been described, but the present exemplary embodiment is not limited to this example. For example, a V-shaped groove may be provided in one of the first holding unit 41 and the second holding unit 42, and one inclined surface as that described in the first exemplary embodiment may be provided in the other of the holding units in which the V-shaped groove is not provided. In other words, at least one of a first inclined surface of the first holding unit 41 and a second inclined surface of the second holding unit 42 may be a part of the V-shaped groove.

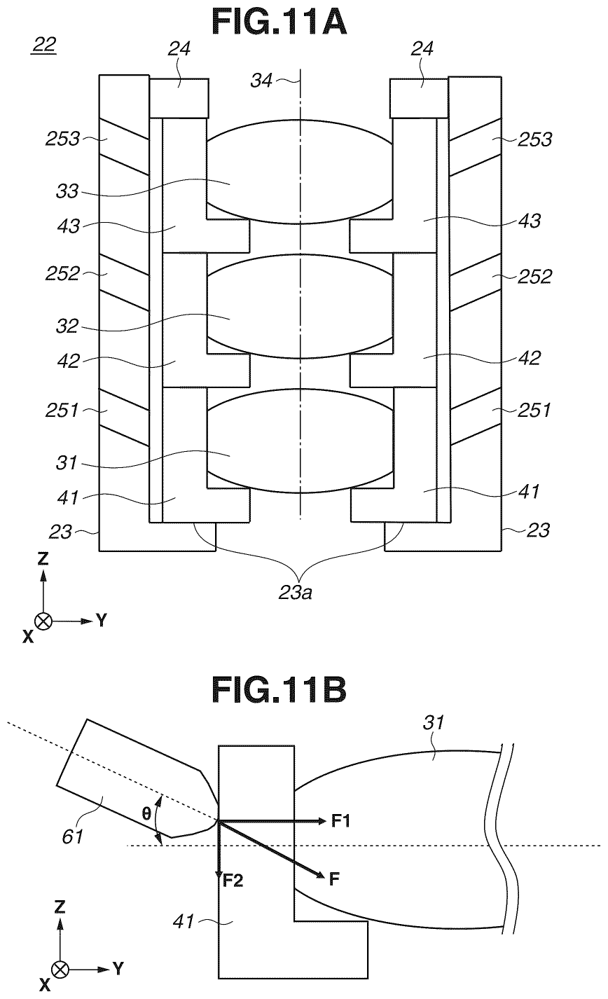

In an objective lens 22 according to a fourth exemplary embodiment, an inclined surface inclined with respect to a direction parallel to the optical axis 34 is not provided in a holding unit of an optical element, and a through-hole included in the lens barrel 23 extends in a direction inclined with respect to a direction orthogonal to the direction parallel to the optical axis 34. FIGS. 11A and 11B are cross-sectional diagrams of the objective lens 22 included in a detection unit according to the present exemplary embodiment. FIG. 11A is a cross-sectional diagram of the objective lens 22 according to the present exemplary embodiment. A first through-hole 251, a second through-hole 252, and a third through-hole 253 provided in the lens barrel 23 according to the present exemplary embodiment extend in a direction inclined with respect to the direction orthogonal to the direction parallel to the optical axis 34. In addition, the first through-hole 251 extends in a direction inclined with respect to a direction orthogonal to a direction parallel to the optical axis 35 of the first optical element 31 (see FIG. 3). The second through-hole 252 extends in a direction inclined with respect to a direction orthogonal to a direction parallel to the optical axis 36 of the second optical element 32 (see FIG. 3). The third through-hole 253 extends in a direction inclined with respect to a direction orthogonal to a direction parallel to an optical axis of the third optical element 33.

FIG. 11B is a schematic diagram illustrating a force applied to the first holding unit 41 by the first adjustment unit 61. The first adjustment unit 61 is inserted into the first through-hole 251 extending in a direction inclined by an angle 0 with respect to the direction orthogonal to the direction parallel to the optical axis 34. By pressing the first holding unit 41 in the inclined direction, a force F1 in the +Y direction is applied to the first holding unit 41, and a position adjustment in the Y-axis direction is performed, and a force in the −Z direction is applied. In the example illustrated in FIG. 11B, a force F2 is applied to the first holding unit 41. By the force F2, the inclination and the uplift of the first holding unit 41 that occur when the position in the Y-axis direction is adjusted may be reduced. Such a function and effect also applies in the case of performing position adjustments by inserting the respective adjustment units into the corresponding through-holes of the second holding unit 42 and the third holding unit 43.

A fifth exemplary embodiment relates to a method for manufacturing a product that is characterized in that a product is manufactured using an exposure apparatus including the above-described objective lens (optical device) 22.

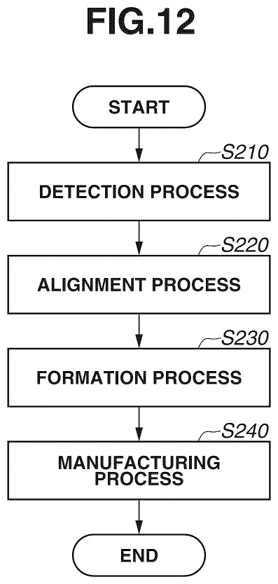

FIG. 12 is a diagram illustrating a flowchart of a method for manufacturing a product that uses the exposure apparatus 1 illustrated in FIG. 1. In step S210, the position of a mark provided on the substrate 16 is detected by the detection unit 21. Next, in step S220, the substrate 16 is aligned based on a detection result in the detection process. In step S230, a pattern is formed on the substrate 16 aligned in the alignment process. Then, in step S240, a product is manufactured from the substrate 16 on which the pattern is formed in the formation process.

The exposure apparatus 1 includes the substrate stage 17 that holds the substrate 16, the detection unit 21, and the illumination optical system 12 that emits light toward the substrate 16. The detection unit 21 includes the first holding unit 41 that holds the first optical element 31, the second holding unit 42 that holds the second optical element 32 and is stacked on the first holding unit 41, and the lens barrel 23 that accommodates the first holding unit 41 and the second holding unit 42 and includes the support surface 23a that supports the first holding unit 41. The first holding unit 41 has the first inclined surface inclined with respect to the optical axis of the first optical element 31 at a position facing the lens barrel 23. The second holding unit 42 has the second inclined surface inclined with respect to the optical axis of the second optical element 32 at a position facing the lens barrel 23. The lens barrel 23 includes the first through-hole 51 that is provided at the position corresponding to the first inclined surface and extends in a first direction orthogonal to the optical axis 35 of the first optical element 31, and the second through-hole 52 that is provided at the position corresponding to the second inclined surface and extends in a second direction orthogonal to the optical axis 36 of the second optical element 32.

Examples of products to be manufactured using the manufacturing method include a semiconductor integrated circuit (IC) element, a liquid crystal display element, a color filter, and a microelectromechanical system (MEMS).

In the formation process, a pattern is formed on a substrate by exposing the substrate (silicon wafer, glass plate, or the like) to which a photosensitive material is applied, for example, using an exposure apparatus (lithography apparatus).

The manufacturing process may include, for example, performing development of a substrate (photosensitive material) on which a pattern is formed, etching of and resist removing from the developed substrate, dicing, bonding, and packaging. Because the detection unit 21 included in the exposure apparatus 1 of the present exemplary embodiment is manufactured in a state in which the inclination and the uplift of the holding unit (optical element) that occur when the position of the holding unit (optical element) is adjusted are reduced, manufacture of the detection unit 21 in which the optical element is accurately aligned. Accordingly, the present disclosure provides improved detection accuracy of the detection unit 21 and manufacture products with improved quality and alignment accuracy.

The present disclosure is not limited to the above-described exemplary embodiments, and various modifications and variations can be made without departing from the spirit and scope of the present disclosure.

According to the present disclosure, a holding apparatus capable of adjusting the position of an optical element can be provided.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims priority to and the benefit of Japanese Patent Application No. 2024-082899, filed May 21, 2024, the entirety of which is incorporated herein by reference.

What is claimed is:

1. A holding apparatus comprising:
a first holding unit configured to hold a first optical element;
a second holding unit configured to hold a second optical element, the second holding unit being stacked on the first holding unit; and
a lens barrel that accommodates the first holding unit and the second holding unit, the lens barrel including a support surface supporting the first holding unit,
wherein the first holding unit has a first surface at a position facing the lens barrel, the first surface being inclined with respect to an optical axis of the first optical element,
wherein the second holding unit has a second surface at a position facing the lens barrel, the second surface being inclined with respect to an optical axis of the second optical element, and
wherein the lens barrel includes a first through-hole that is provided at a position corresponding to the first surface and extends in a first direction orthogonal to the optical axis of the first optical element, and a second through-hole that is provided at a position corresponding to the second surface and extends in a second direction orthogonal to the optical axis of the second optical element.

2. The holding apparatus according to claim 1, wherein an angle by which the first surface is inclined is different from an angle by which the second surface is inclined.

3. The holding apparatus according to claim 2, wherein an angle by which the first surface is inclined is greater than an angle by which the second surface is inclined.

4. The holding apparatus according to claim 1,
wherein a first force is applied to the first surface to adjust a position of the first optical element in the first direction, and
wherein a second force is applied to the second surface to adjust a position of the second optical element in the second direction.

5. The holding apparatus according to claim 1,
wherein the first surface is at a distance from the optical axis of the first optical element that decreases as a distance from the support surface increases, and
wherein the second surface is at a distance from the optical axis of the second optical element that decreases as a distance from the support surface increases.

6. The holding apparatus according to claim 1, wherein the first holding unit contacts the second holding unit.

7. The holding apparatus according to claim 1, wherein the first surface covers an entire circumference of the first holding unit.

8. The holding apparatus according to claim 1, wherein the first surface is provided in a part of a circumference of the first holding unit.

9. The holding apparatus according to claim 1, wherein the first surface is provided at a position corresponding to a center of gravity of the first holding unit.

10. The holding apparatus according to claim 1, wherein at least one of the first surface and the second surface is a part of a V-shaped groove.

11. The holding apparatus according to claim 1, wherein a position of the optical axis of the first optical element coincides with a position of the optical axis of the second optical element.

12. The holding apparatus according to claim 1,
wherein the lens barrel accommodates a third holding unit that holds a third optical element so as to be stacked on the second holding unit,
wherein the third holding unit has a third inclined surface facing the lens barrel and inclined with respect to an optical axis of the third optical element, and
wherein the lens barrel includes a third through-hole provided at a position corresponding to the third inclined surface and extending in a third direction orthogonal to the optical axis of the third optical element.

13. The holding apparatus according to claim 1, wherein the lens barrel includes:
a third through-hole that is provided at a position corresponding to the first surface and extends in a direction orthogonal to the optical axis of the first optical element different from the first direction, and
a fourth through-hole that is provided at a position corresponding to the second surface and extends in a direction orthogonal to the optical axis of the second optical element different from the second direction.

14. The holding apparatus according to claim 1, wherein a plurality of first through-holes is included, the plurality of first through-holes being provided in the lens barrel around the optical axis of the first optical element at an interval of a predetermined angle.

15. A holding apparatus comprising:
a first holding unit configured to hold a first optical element;
a second holding unit configured to hold a second optical element, the second holding unit being stacked on the first holding unit; and
a lens barrel configured to accommodate the first holding unit and the second holding unit, the lens barrel including a support surface supporting the first holding unit,
wherein the lens barrel includes a first through-hole that is provided at a position corresponding to the first holding unit and extends in a direction inclined with respect to a first direction orthogonal to a direction parallel to an optical axis of the first optical element, and a second through-hole that is provided at a position corresponding to the second holding unit and extends in a direction inclined with respect to a second direction orthogonal to a direction parallel to an optical axis of the second optical element.

16. A method for manufacturing an optical device, the method comprising:
adjusting, by applying a force to a first inclined surface included in a first holding unit from a first direction orthogonal to a direction parallel to an optical axis of a first optical element held by the first holding unit, a position of the first optical element in the first direction;
adjusting, by applying a force to a second inclined surface included in a second holding unit being stacked on the first holding unit from a second direction orthogonal to a direction a parallel to an optical axis of a second optical element held by the second holding unit, a position of the second optical element in the second direction; and
fixing relative positions of the first optical element and the second optical element.

17. The method for manufacturing an optical device according to claim 16, wherein an elastic member is placed on the second holding unit when performing the fixing the relative positions

18. The method for manufacturing an optical device according to claim 16, wherein the relative positions of the first optical element and the second optical element are fixed by a retainer collar.

19. A method for manufacturing an optical device, the method comprising:
adjusting, by applying a force from a direction inclined with respect to a first direction orthogonal to a direction parallel to an optical axis of a first optical element held by a first holding unit, a position of the first optical element in the first direction;
adjusting, by applying a force from a direction inclined with respect to a second direction orthogonal to a direction parallel to an optical axis of a second optical element held by a second holding unit stacked on the first holding unit, a position of the second optical element in the second direction; and
fixing relative positions of the first optical element and the second optical element.

20. An apparatus for exposing a substrate, the apparatus comprising:
a substrate stage configured to hold the substrate;
a detection unit configured to detect a position of at least one of a mark of the substrate and a mark of the substrate stage; and
an illumination optical system configured to emit light toward the substrate, wherein the detection unit includes:
a first holding unit configured to hold a first optical element;
a second holding unit configured to hold a second optical element, the second holding unit being stacked on the first holding unit; and
a lens barrel that accommodates the first holding unit and the second holding unit, the lens barrel including a support surface supporting the first holding unit,
wherein the first holding unit has a first surface at a position facing the lens barrel, the first surface being inclined with respect to an optical axis of the first optical element,
wherein the second holding unit has a second surface at a position facing the lens barrel, the second surface being inclined with respect to an optical axis of the second optical element,
wherein the lens barrel includes a first through-hole that is provided at a position corresponding to the first surface and extends in a first direction orthogonal to a direction parallel to the optical axis of the first optical element, and a second through-hole that is provided at a position corresponding to the second surface and extends in a second direction orthogonal to a direction parallel to the optical axis of the second optical element, and
wherein the light from the illumination optical system is emitted toward the substrate held by the substrate stage aligned based on a detection result obtained by the detection unit.

21. A method for manufacturing a product using the apparatus according to claim 20, the method comprising:
detecting, by the detection unit, a position of a mark of a substrate;
aligning the substrate based on a result obtained in the detecting;
forming a pattern on the aligned substrate; and
manufacturing the product from the substrate on which the pattern is formed.

22. A measurement apparatus, comprising:
a substrate stage configured to hold a substrate; and
a detection unit configured to detect a position of at least one of a mark of the substrate held by the substrate stage and a mark of the substrate stage,
wherein the detection unit includes:
a first holding unit configured to hold a first optical element;
a second holding unit configured to hold a second optical element, the second holding unit being stacked on the first holding unit; and
a lens barrel that accommodates the first holding unit and the second holding unit, the lens barrel including a support surface supporting the first holding unit,
wherein the first holding unit has a first surface at a position facing the lens barrel, the first surface being inclined with respect to an optical axis of the first optical element,
wherein the second holding unit has a second surface at a position facing the lens barrel, the second surface being inclined with respect to an optical axis of the second optical element, and
wherein the lens barrel includes a first through-hole that is provided at a position corresponding to the first surface and extends in a first direction orthogonal to a direction parallel to the optical axis of the first optical element, and a second through-hole that is provided at a position corresponding to the second surface and extends in a second direction orthogonal to a direction parallel to the optical axis of the second optical element.
